(19) United States
(12) Patent Application Publication
(10) Pub. No.: US 2022/0149185 A1
(43) Pub. Date: May 12, 2022

(54) METHOD FOR MAKING LDMOS DEVICE

(71) Applicant: Hua Hong Semiconductor (Wuxi) Limited, Wuxi (CN)

(72) Inventors: Mingxu FANG, Wuxi (CN); Yu CHEN, Wuxi (CN); Hualun CHEN, Wuxi (CN)

(73) Assignee: Hua Hong Semiconductor (Wuxi) Limited, Wuxi (CN)

(21) Appl. No.: 17/406,444

(22) Filed: Aug. 19, 2021

(30) Foreign Application Priority Data
Nov. 10, 2020 (CN) 202011247661.6

(51) Int. Cl. H01L 29/66; H01L 29/78; H01L 29/423

(52) U.S. Cl. CPC H01L 29/66681; H01L 21/31111; H01L 29/42368; H01L 29/7816

(57) ABSTRACT

A method for making an LDMOS device including forming a first ion doped region in an epitaxial layer of a first region and removing a first oxide layer of the first region, the first oxide layer being formed on the epitaxial layer; forming a second oxide layer on the epitaxial layer and the remaining first oxide layer; forming a second ion doped region in the epitaxial layer of a second region, the first region and the second region having no overlapped region; and forming a polysilicon layer on the second oxide layer; removing the polysilicon layer, the first oxide layer and the second oxide layer of a third region.

### CROSS-REFERENCES TO RELATED APPLICATION

This application claims priority to Chinese patent application No. CN 202011247661.6, filed on Nov. 10, 2020, and entitled “METHOD FOR MAKING LDMOS DEVICE”, the disclosure of which is incorporated herein by reference in its entirety.

### TECHNICAL FIELD

The present application relates to semiconductor manufacturing, in particular to a method for making a Laterally-Diffused Metal-Oxide Semiconductor (LDMOS) device.

### BACKGROUND

LDMOS is widely applied to power integrated circuits due to its compatibility with a Complementary Metal Oxide Semiconductor (CMOS) process. For LDMOS devices, Gate Induced Drain Leakage (GIDL) current, Break Voltage (BV) and Hot Carrier Injection (HCI) effect are important parameters to evaluate the electrical performance of LDMOS devices.

FIG. 1 illustrates a cross-sectional schematic view of an LDMOS device provided in the related art. Referring to FIG. 1, a first ion doped region 111 and a second ion doped region 112 are formed in a substrate 110, a third ion doped region 113 is formed in the first ion doped region 111, a fourth ion doped region 114 is formed in the second ion doped region 112, and the doping concentration of the third ion doped region 113 and the fourth ion doped region 114 is higher than the doping concentration of the first ion doped region 111 and the second ion doped region 112. A gate oxide 120 is formed on the substrate 110, and a gate 130 is formed on the gate oxide 120. The first region 101 is a region where the first ion doped region 111 is controlled through the gate 130, and the second region 102 is a region where the second ion doped region 112 is controlled through the gate 130.

Since the gate oxide is thin, the gate induced drain leakage current of the LDMOS device provided in the related art is large, resulting in low break voltage and weak HCI resistance.

### BRIEF SUMMARY

According to some embodiments in this application, a method for making an LDMOS device is disclosed in the following steps: forming a first ion doped region in an epitaxial layer of a first region and removing a first oxide layer of the first region, the first oxide layer being formed on the epitaxial layer; forming a second oxide layer on the epitaxial layer and the remaining first oxide layer; forming a second ion doped region in the epitaxial layer of a second region, the first region and the second region having no overlapped region; forming a polysilicon layer on the second oxide layer; removing the polysilicon layer, the first oxide layer and the second oxide layer of a third region, the remaining first oxide layer and second oxide layer forming a gate oxide of the LDMOS device, the remaining polysilicon layer forming a gate of the LDMOS device, the gate oxide and the gate being step-shaped.

In example embodiments, the step of forming the first ion doped region in the epitaxial layer of the first region and removing the first oxide layer of the first region includes covering the first oxide layer with a photoresist and exposing the first region by adopting a photolithography process; implanting impurities containing first type of ions into the first region by adopting a first ion implantation process by using the photoresist as a mask to form the first ion doped region in the epitaxial layer; removing the first oxide layer and the photoresist of the first region.

In example embodiments, the step of removing the first oxide layer of the first region includes: removing the first oxide layer of the first region by adopting a wet etching process.

In example embodiments, the step of forming the second ion doped region in the epitaxial layer of the second region includes covering the second oxide layer with a photoresist and exposing the second region by adopting a photolithography process; implanting impurities containing second type of ions into the second region by adopting a second ion implantation process by using the photoresist as a mask to form the second ion doped region in the epitaxial layer; removing the photoresist.

In example embodiments, the step of removing the polysilicon layer, the first oxide layer and the second oxide layer of the third region includes covering the polysilicon layer with a photoresist and exposing the third region by adopting a photolithography process; performing etching by using the photoresist as a mask till the epitaxial layer of the third region is exposed; removing the photoresist.

In example embodiments, before forming the first ion doped region in the epitaxial layer of the first region, the method further includes: forming the first oxide layer on the epitaxial layer by adopting a Rapid Thermal Annealing (RTO) process.

In example embodiments, after removing the polysilicon layer, the first oxide layer and the second oxide layer of the third region, the method further includes: forming a third ion doped region in the first ion doped region and forming a fourth ion doped region in the second ion doped region, the doping concentration of the third ion doped region and the fourth ion doped region being higher than the doping concentration of the first ion doped region and the second ion doped region.

In example embodiments, the epitaxial layer is formed on a substrate, a fifth ion doped region is also formed in the epitaxial layer, and the fifth ion doped region is formed below the first ion doped region and the second ion doped region.

The technical solution of the present application has the following advantages:

In the manufacturing process of the LDMOS device, after the first ion doped region is formed, the first oxide layer of other regions except the first ion doped region is reserved, such that the gate oxide of the obtained LDMOS device is step-shaped, and the thickness of the gate oxide in the overlapped region of the gate and the second ion doped region is increased, thus reducing the gate induced drain leakage current of the LDMOS device, and increasing the break voltage of the device; at the same time, due to the increase of the thickness of the film layer in the overlapped region, the intensity of the gate-drain electric field of the device is reduced, thus improving the HCI resistance of the device.

### BRIEF DESCRIPTION OF THE DRAWINGS

In order to more clearly describe the specific embodiments of the present application or the technical solution in the prior art, the drawings which need be used in the description of the specific embodiments or the prior art will be briefly introduced below. The drawings described below are some embodiments of the present application. Those skilled in the art may obtain other drawings according to these drawings without contributing any inventive labor.

FIG. 1 is a cross-sectional schematic view of an LDMOS device provided in the prior art.

FIG. 2 is a flowchart of a method for making an LDMOS device provided by one exemplary embodiment of the present application.

FIG. 3 is a cross-sectional schematic view when the first oxide layer is formed on the epitaxial layer in the method for making an LDMOS device provided in an exemplary embodiment of the present application.

FIG. 4 is a cross-sectional schematic view when the first ion doped region is formed in the first region in the method for making an LDMOS device provided in an exemplary embodiment of the present application.

FIG. 5 is a cross-sectional schematic view when the photoresist is removed after the first ion doped region is formed in the method for making an LDMOS device provided in an exemplary embodiment of the present application.

FIG. 6 is a cross-sectional schematic view when the second oxide layer is formed on the epitaxial layer and the remaining first oxide layer in the method for making an LDMOS device provided in an exemplary embodiment of the present application.

FIG. 7 is a cross-sectional schematic view when the second ion doped region is formed in the epitaxial layer of the second region in the method for making an LDMOS device provided in an exemplary embodiment of the present application.

FIG. 8 is a cross-sectional schematic view when the polysilicon layer is formed on the second oxide layer in the method for making an LDMOS device provided in an exemplary embodiment of the present application.

FIG. 9 is a cross-sectional schematic view of the formed gate oxide and gate in the method for making an LDMOS device provided in an exemplary embodiment of the present application.

FIG. 10 is a cross-sectional schematic view when the third ion doped region and the fourth ion doped region are formed in the method for making an LDMOS device provided in an exemplary embodiment of the present application.

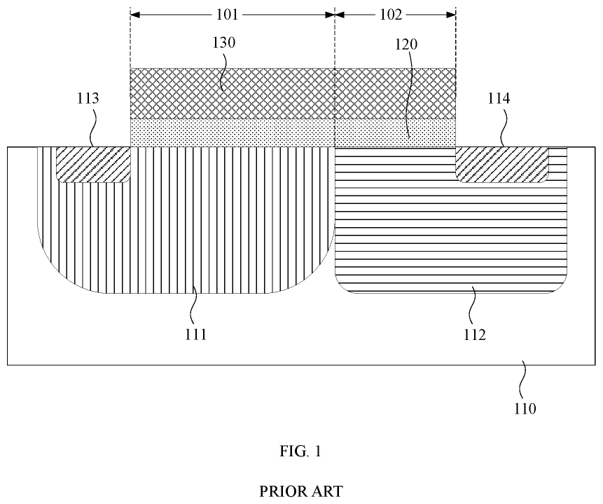

### DETAILED DESCRIPTION

The technical solution of the present application will be described below clearly and completely with reference to the drawings. The described embodiments are partial embodiments of the present application, instead of all embodiments. Based on the embodiments of the present application, all other embodiments obtained by those skilled in the art without contributing any inventive labor shall fall into the scope of protection of the present application.

In the description of the present application, it should be noted that the orientation or position relationships indicated by the terms such as “center”, “top”, “bottom”, “left”, “right”, “vertical”, “horizontal”, “inside” and “outside” are based on the orientation or position relationships illustrated in the drawings, for the purpose of conveniently describing the present application and simplifying the description, rather than indicating or implying that the device or component referred to must have a specific orientation and be constructed and operated in a specific orientation, and shall not be understood as limitations to the present application. In addition, the terms “first”, “second” and “third” are used only for the purpose of description, and shall not be understood as indicating or implying relative importance.

In the description of the present application, it should be noted that, unless otherwise specified and limited, the terms “mounting”, “interconnection” and “connection” shall be understood in a broad sense. For example, it may be a fixed connection, detachable connection, or integrated connection; it may be mechanical connection or electrical connection; it may be direct connection or indirect connection through an intermediary; it may also be internal connection of two components, wireless connection or wired connection. Those skilled in the art may understand the specific meaning of the above terms in the present application according to the specific circumstances.

In addition, the technical features described below in different embodiments of the present application can be combined with each other as long as they do not constitute a conflict.

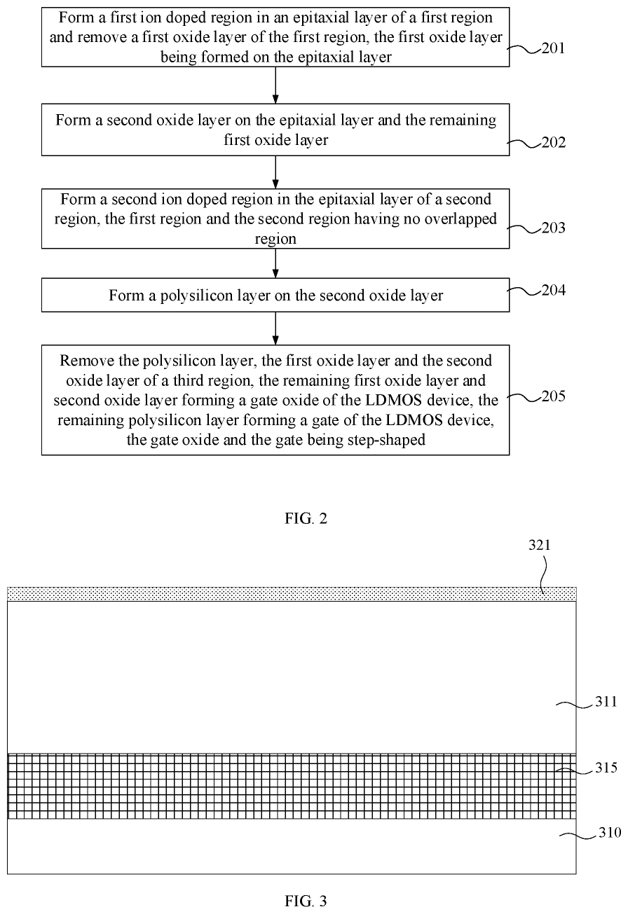

Referring to FIG. 2, it illustrates a flowchart of a method for making an LDMOS provided in an exemplary embodiment of the present application. The method includes the following steps:

In step 201, a first ion doped region is formed in an epitaxial layer of a first region and a first oxide layer of the first region is removed. The first oxide layer is formed on the epitaxial layer.

In example embodiments, before step 201, the method further includes forming a first oxide layer on the epitaxial layer by adopting an RTO process.

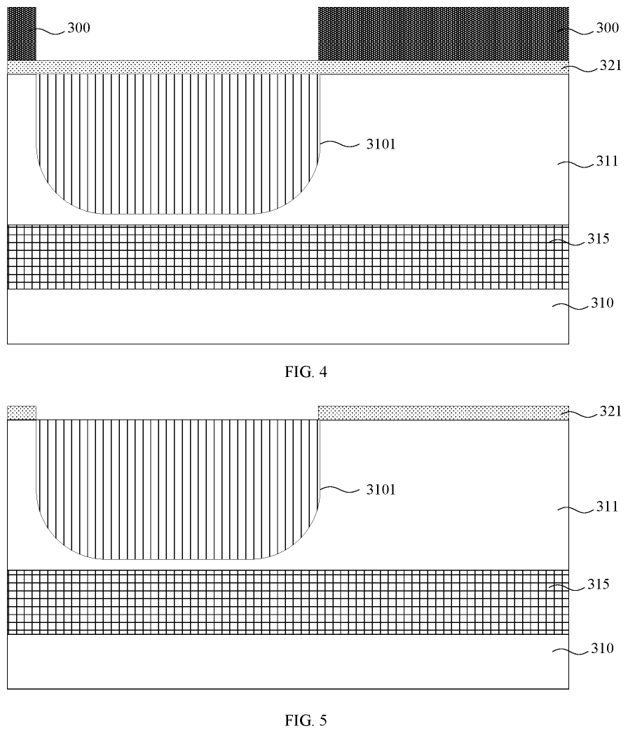

Referring to FIG. 3, it illustrates a cross-sectional schematic view when the first oxide layer is formed on the epitaxial layer; referring to FIG. 4, it illustrates a cross-sectional schematic view when the first ion doped region is formed in the first region; referring to FIG. 5, it illustrates a cross-sectional schematic view when the photoresist is removed after the first ion doped region is formed.

In example embodiments, referring to FIG. 3, an epitaxial layer 311 is formed on a substrate 310, and a fifth ion doped region 315 (which may be called as a buried layer (BL)) is formed in the epitaxial layer 311. The epitaxial layer 311 may be formed on the substrate 310 through epitaxial growth. The fifth ion doped region 315 is formed in the epitaxial layer 311 by adopting an ion implantation process and a high-temperature thermal propulsion process.

In example embodiments, referring to FIG. 4 and FIG. 5, step 201 includes, but not limited to, covering the first oxide layer with a photoresist 300 and exposing the first region (the first region is area region requiring a first ion implantation process) by adopting a photolithography process; implanting impurities containing first type of ions into the first region by adopting the first ion implantation process by using the photoresist 300 as a mask to form a first ion doped region 3101 in the epitaxial layer 311; removing the first oxide layer 311 and the photoresist 300 of the first region. Herein, the photoresist 300 may be removed after the first oxide layer 311 of the first region is removed by adopting a wet etching process.

In step 202, a second oxide layer is formed on the epitaxial layer and the remaining first oxide layer.

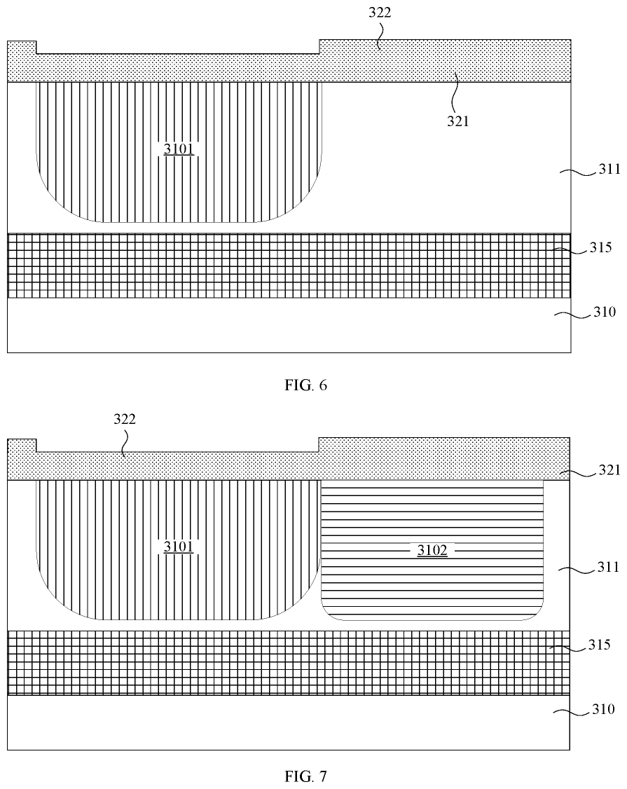

Referring to FIG. 6, it illustrates a cross-sectional schematic view when the second oxide layer is formed on the epitaxial layer and the remaining first oxide layer. In example embodiments, referring to FIG. 6, a second oxide layer 322 may be formed by depositing silicon dioxide (SiO₂) on the epitaxial layer 311 and the remaining first oxide layer 321 through a Chemical Vapor Deposition (CVD) process (for example, Plasma Enhanced Chemical Vapor Deposition (PECVD) process). Since the first oxide layer 321 still exists in other regions except the first region, the thickness of the oxide layer (second oxide layer 322) of the first region is smaller than the thickness of the oxide layer of the other regions (first oxide layer 321 and second oxide layer 322).

In step 203, a second ion doped region is formed in the epitaxial layer of a second region. The first region and the second region have no overlapped region.

Referring to FIG. 7, it illustrates a cross-sectional schematic view when the second ion doped region is formed in the epitaxial layer of the second region. In example embodiments, referring to FIG. 7, step 203 includes, but not limited to, covering the second oxide layer 322 with a photoresist and exposing a second region (the second region is a region requiring the second ion implantation process) by adopting a photolithography process; implanting impurities containing second type of ions into the second region by adopting the second ion implantation process by using the photoresist as a mask to form a second ion doped region 3102 in the epitaxial layer 311 (which may be called as a drift region); removing the photoresist. Herein, when the first type of ions are P (positive)-type ions, the second type of ions are N (negative)-type ions; when the first type of ions are N (negative)-type ions, the second type of ions are P (positive)-type ions.

In step 204, a polysilicon layer is formed on the second oxide layer.

Referring to FIG. 8, it illustrates a cross-sectional schematic view when the polysilicon layer is formed on the second oxide layer. In example embodiments, referring to FIG. 8, a polysilicon layer 330 may be formed on the second oxide layer 322 by adopting a CVD process.

In step 205, the polysilicon layer, the first oxide layer and the second oxide layer of a third region are removed. The remaining first oxide layer and second oxide layer form a gate oxide of the LDMOS device, the remaining polysilicon layer forms a gate of the LDMOS device, and the gate oxide and the gate are step-shaped.

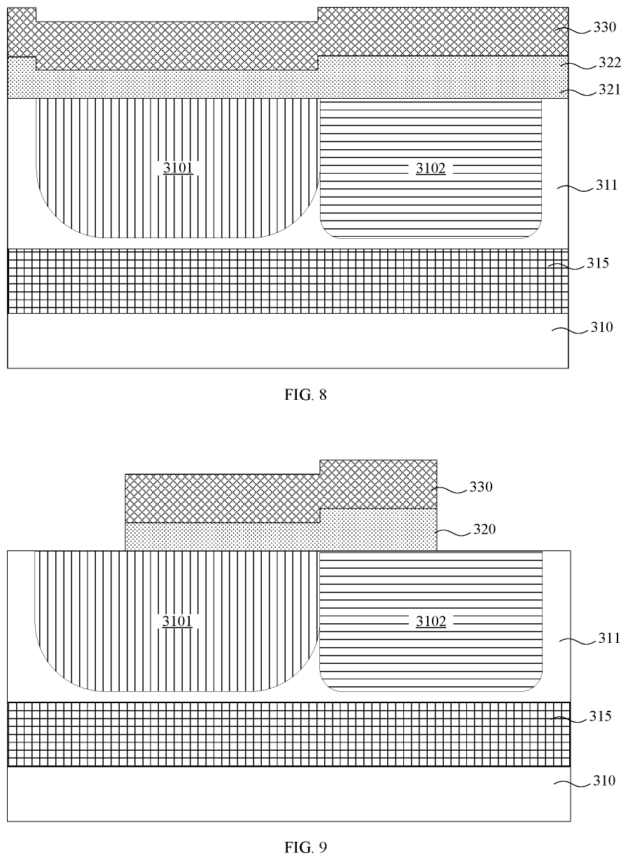

Referring to FIG. 9, it illustrates a cross-sectional schematic view of the formed gate oxide and gate. In example embodiments, referring to FIG. 9, step 205 includes, but not limited to, covering the polysilicon layer 330 with a photoresist and exposing a third region (the third region is a region to be etched) by adopting a photolithography process; performing etching by using the photoresist as a mask till the epitaxial layer 311 of the third region is exposed; and removing the photoresist. The remaining first oxide layer 321 and second oxide layer 322 form a gate oxide 320 of the LDMOS device, the remaining polysilicon layer 330 forms a gate of the LDMOS device, and the gate oxide 320 and the gate 330 are step-shaped.

In an embodiment of the present application, the step-shaped gate oxide 320 is formed in the forming process of the first ion doped region 3101, and the photolithography mask used in the forming process of the first ion doped region 3101 is used, and the thickness of the gate oxide 320 of the second region 302 is increased without any additional photolithography process and photolithography mask.

In summary, in an embodiment of the present application, in the manufacturing process of the LDMOS device, after the first ion doped region is formed, the first oxide layer of other regions except the first ion doped region is reserved, such that the gate oxide of the obtained LDMOS device is step-shaped, and the thickness of the gate oxide in the overlapped region of the gate and the second ion doped region is increased, thus reducing the gate induced drain leakage current of the LDMOS device, and increasing the break voltage of the device; at the same time, due to the increase of the thickness of the film layer in the overlapped region, the intensity of the gate-drain electric field of the device is reduced, thus improving the HCI resistance of the device.

In example embodiments, after step 205, the method further includes forming a third ion doped region in the first ion doped region and forming a fourth ion doped region in the second ion doped region.

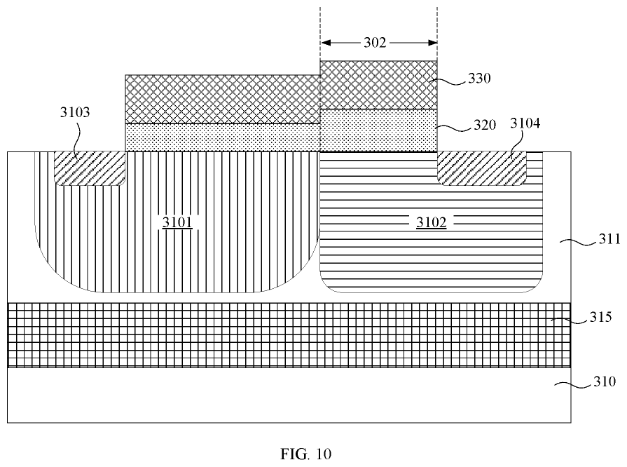

Referring to FIG. 10, it illustrates a cross-sectional schematic view when the third ion doped region and the fourth ion doped region are formed. In example embodiments, referring to FIG. 10, the third ion doped region 3103 and the fourth ion doped region 3104 are heavily doped regions, and the doping concentration thereof is higher than the doping concentration of the first ion doped region 3101 and the second ion doped region 3102. In example embodiments, the third ion doped region 3103 may be a source of the LDMOS device, and the fourth ion doped region 3104 may be a drain of the LDMOS device. The third ion doped region 3103 and the fourth ion doped region 3104 may be formed by adopting a photolithography process and source drain (SD) implantation.

In example embodiments, in an embodiment of the present application, the top view shape of the third ion doped region 3103 and the fourth ion doped region 3104 is rectangular. If the third ion doped region 3103 is the source of the LDMOS device and the fourth ion doped region 3104 is the drain of the LDMOS device, the length of the third ion doped region 3103 (i.e., the length of the top view rectangle of the third ion doped region 3103) is greater than the length of the fourth ion doped region 3104 (i.e., the length of the top view rectangle of the four ion doped region 3104).

Referring to FIG. 10, the second region 302 is a region where the second ion doped region 3102 (the second ion doped region 3102 may be a drift region) is controlled through the gate 330, and the thickness of the gate oxide 320 of the second region 302 is larger.

In the embodiment of the present application, the impurities implanted into the first ion doped region 3101 and the fifth ion doped region 3105 include first type of ions, and the impurities implanted into the epitaxial layer 311, the second ion doped region 3102, the third ion doped region 3103 and the fourth ion doped region 3104 include second type of ions.

The above embodiments are only examples for clear description, instead of limitations to the embodiments. On the basis of the above description, those skilled in the art may make other different types of changes or variations. It is not necessary and impossible to enumerate all the embodiments here. The apparent changes or variations thus derived are still within the scope of protection of the present application.

What is claimed is:

1. A method for making an LDMOS device, wherein the method comprises:
forming a first ion doped region in an epitaxial layer of a first region and removing a first oxide layer of the first region, the first oxide layer being formed on the epitaxial layer;
forming a second oxide layer on the epitaxial layer and the remaining first oxide layer;
forming a second ion doped region in the epitaxial layer of a second region, the first region and the second region having no overlapped region;
forming a polysilicon layer on the second oxide layer; and
removing the polysilicon layer, the first oxide layer and the second oxide layer of a third region, the remaining first oxide layer and second oxide layer forming a gate oxide of the LDMOS device, the remaining polysilicon layer forming a gate of the LDMOS device, the gate oxide and the gate being step-shaped.

2. The method according to claim 1, wherein the step of forming the first ion doped region in the epitaxial layer of the first region and removing the first oxide layer of the first region comprises:
covering the first oxide layer with a photoresist and exposing the first region by adopting a photolithography process;
implanting impurities containing first type of ions into the first region by adopting a first ion implantation process by using the photoresist as a mask to form the first ion doped region in the epitaxial layer; and
removing the first oxide layer and the photoresist of the first region.

3. The method according to claim 2, wherein the step of removing the first oxide layer of the first region comprises:
removing the first oxide layer of the first region by adopting a wet etching process.

4. The method according to claim 2, wherein the step of forming the second ion doped region in the epitaxial layer of the second region comprises:
covering the second oxide layer with a photoresist and exposing the second region by adopting a photolithography process;
implanting impurities containing second type of ions into the second region by adopting a second ion implantation process by using the photoresist as a mask to form the second ion doped region in the epitaxial layer; and
removing the photoresist.

5. The method according to claim 4, wherein the step of removing the polysilicon layer, the first oxide layer and the second oxide layer of the third region comprises:
covering the polysilicon layer with a photoresist and exposing the third region by adopting a photolithography process;
performing etching by using the photoresist as a mask till the epitaxial layer of the third region is exposed; and
removing the photoresist.

6. The method according to claim 5, wherein before forming the first ion doped region in the epitaxial layer of the first region, the method further comprises:
forming the first oxide layer on the epitaxial layer by adopting an RTO process.

7. The method according to claim 6, wherein after removing the polysilicon layer, the first oxide layer and the second oxide layer of the third region, the method further comprises:
forming a third ion doped region in the first ion doped region and forming a fourth ion doped region in the second ion doped region, the doping concentration of the third ion doped region and the fourth ion doped region being higher than the doping concentration of the first ion doped region and the second ion doped region.

8. The method according to claim 1, wherein the epitaxial layer is formed on a substrate, a fifth ion doped region is also formed in the epitaxial layer, and the fifth ion doped region is formed below the first ion doped region and the second ion doped region.
